(19) United States
(12) Patent Application Publication
(10) Pub. No.: US 2026/0235958 A1
(43) Pub. Date: Aug. 13, 2026

(54) SUBSTRATE PROCESSING APPARATUS

(71) Applicant: Samsung Electronics Co., Ltd., Suwon-si (KR)

(72) Inventors: Sanghwan LEE, Suwon-si (KR); Sunghwan SHIN, Suwon-si (KR); Hyun Chol CHOI, Suwon-si (KR)

(73) Assignee: Samsung Electronics Co., Ltd., Suwon-si (KR)

(21) Appl. No.: 19/299,638

(22) Filed: Aug. 14, 2025

(30) Foreign Application Priority Data
Feb. 11, 2025 (KR) 10-2025-0017267

(51) Int. Cl. G03F 7/20

(52) U.S. Cl. CPC G03F 7/2026; G03F 7/2004

(57) ABSTRACT

A substrate processing apparatus includes an ultraviolet (UV) exposure apparatus configured to irradiate a reticle with a UV beam and an extreme ultraviolet (EUV) exposure apparatus configured to irradiate the reticle, which has been irradiated with the UV beam by the UV exposure apparatus, with an EUV beam. The UV exposure apparatus includes a UV exposure chamber configured to house the reticle, a supporting portion configured to support the reticle in the UV exposure chamber, and a UV lamp on a bottom surface of the UV exposure chamber and facing the supporting portion in a first direction intersecting the bottom surface. The UV lamp is configured to irradiate the reticle with the UV beam to remove an oxide layer on the reticle.

### CROSS-REFERENCE TO RELATED APPLICATIONS

This U.S. non-provisional application claims the benefit of Korean Patent Application No. 10-2025-0017267, filed on Feb. 11, 2025, in the Korean Intellectual Property Office, the disclosure of which is incorporated herein by reference in its entirety.

### BACKGROUND

Example embodiments relate to a substrate processing apparatus including an exposure apparatus.

Due to continued reductions in semiconductor line widths, light sources with even shorter wavelengths are used in semiconductor device fabrication. For example, extreme ultraviolet (EUV) light is now being used. Because of the absorption characteristics of EUV, a reflective EUV mask is used in the EUV exposure process. As the exposure process becomes relatively more complex, minor defects in the EUV mask can cause errors in the circuit pattern formed on the wafer. For instance, the presence of impurities on the EUV mask may result in defects.

### SUMMARY

Some example embodiments provide a substrate processing apparatus configured to perform an exposure process with improved reliability by removing impurities on an EUV mask.

However, example embodiments of the present disclosure are not limited thereto and other example embodiments may be clearly understood from the following description by those skilled in the art.

According to some example embodiments, a substrate processing apparatus includes an ultraviolet (UV) exposure apparatus configured to irradiate a reticle with a UV beam and an extreme ultraviolet (EUV) exposure apparatus configured to irradiate the reticle, which has been irradiated with the UV beam by the UV exposure apparatus, with an EUV beam. The UV exposure apparatus includes a UV exposure chamber configured to house the reticle, a supporting portion configured to support the reticle in the UV exposure chamber, and a UV lamp on a bottom surface of the UV exposure chamber and facing the supporting portion in a first direction that intersects the bottom surface. The UV lamp is configured to irradiate the reticle with UV beams to remove an oxide layer on a surface of the reticle.

According to some example embodiments, a substrate processing apparatus includes an ultraviolet (UV) exposure apparatus configured to irradiate a reticle pod, which comprises a reticle, a base configured to support the reticle, and a cover configured to cover the reticle on the base, with a UV beam and an extreme ultraviolet (EUV) exposure apparatus configured to perform an EUV exposure process on the reticle pod which had been irradiated with the UV beam by the UV exposure apparatus. The UV exposure apparatus includes a cover storage configured to remove the cover of the reticle pod, a UV exposure chamber configured to house the reticle pod with the cover removed, a UV lamp on a bottom surface of the UV exposure chamber, a pivot spaced apart from the UV lamp in a first direction intersecting the bottom surface, and configured to rotate about a rotating axis in a direction intersecting the first direction, and a bracket connected to the pivot and configured to rotate about the rotating axis, the bracket contacting the reticle of the reticle pod. The UV lamp is configured to irradiate a main surface of the reticle with the UV beam to remove an oxide layer on the main surface of the reticle.

According to some example embodiments, a substrate processing apparatus is configured to perform an exposure process on a reticle pod comprising a reticle, a base configured to support the reticle, and a cover configured to cover the reticle on the base. The substrate processing apparatus includes a load lock configured to receive the reticle pod which has been exposed to atmosphere and create a vacuum environment in the load lock after receiving the reticle pod, a mask inspection apparatus configured to perform optical inspection on the reticle of the reticle pod, an ultraviolet (UV) exposure apparatus configured to irradiate the reticle, on which the optical inspection has been performed, with a UV beam, an extreme ultraviolet (EUV) exposure apparatus configured to perform an EUV exposure process on the reticle which has been irradiated with the UV beam in the UV exposure apparatus, and a transfer robot configured to transfer the reticle pod between the load lock, the mask inspection apparatus, the UV exposure apparatus, and the EUV exposure apparatus. The UV exposure apparatus includes a cover storage configured to remove the cover of the reticle pod received from the transfer robot, a UV exposure chamber configured to house the reticle pod with the cover removed, a supporting portion configured to support the reticle of the reticle pod in the UV exposure chamber, and a UV lamp spaced apart from the supporting portion in a first direction intersecting a bottom surface of the UV exposure chamber and aligned to face a main surface of the reticle. The UV lamp is configured to irradiate the main surface of the reticle with the UV beam to remove an oxide layer on the main surface of the reticle, the reticle being supported by the supporting portion.

According to some example embodiments, a substrate processing method using a substrate processing apparatus includes transferring a reticle pod including an inner pod configured to house a reticle to a UV exposure apparatus, removing a cover of the inner pod from the reticle, and transferring the reticle to a UV exposure chamber in the UV exposure apparatus, mounting the reticle on a bracket in the UV exposure chamber such that a main surface of the reticle faces a UV lamp, removing an oxide layer formed on the main surface of the reticle by irradiating the main surface of the reticle with a UV beam, using the UV lamp, and mounting the cover of the inner pod onto the reticle again and transferring the inner pod configured to house the reticle to an EUV exposure apparatus.

According to some example embodiments, a substrate processing method includes receiving, in a load lock, a reticle pod which has been exposed to atmosphere, the reticle pod including a reticle, a base configured to support the reticle, and a cover configured to cover the reticle on the base; creating a vacuum environment in the load lock after receiving the reticle pod; transferring the reticle pod to an ultraviolet (UV) exposure apparatus; irradiating the reticle with a UV beam using the UV exposure apparatus; transferring the reticle pod to an extreme ultraviolet (EUV) exposure apparatus; and performing an extreme ultraviolet (EUV) exposure process on the reticle which has been irradiated with the UV beam. Irradiating the reticle with the UV beam includes, removing the cover of the reticle pod, housing the reticle pod with the cover removed, supporting the reticle of the reticle pod, and irradiating a main surface of the reticle with the UV beam to remove an oxide layer on the main surface of the reticle. The main surface of the reticle is irradiated with the UV beam irradiated from a UV lamp spaced apart from the reticle in a first direction aligned to face the main surface of the reticle. According to some example embodiments, the substrate processing method further includes performing optical inspection on the reticle included in the reticle pod; and irradiating the reticle, on which the optical inspection has been performed, with the UV beam. According to some example embodiments, the supporting the reticle of the reticle pod includes contacting the reticle with a bracket connected to a pivot spaced apart from the UV lamp in the first direction and configured to rotate about a rotating axis in a direction intersecting the first direction. According to some example embodiments, the bracket is configured to rotate together with the pivot and contact the reticle when the reticle is positioned below the pivot in the first direction. According to some example embodiments, the performing the EUV exposure process on the reticle includes irradiating the main surface of the reticle, from which the oxide layer has been removed, with an EUV beam.

### BRIEF DESCRIPTION OF THE DRAWINGS

These and/or other aspects, features, and advantages of the example embodiments will become apparent and more readily appreciated from the following description of example embodiments, taken in conjunction with the accompanying drawings.

FIG. 1 is a schematic block diagram illustrating different paths or routes taken by a reticle pod within the substrate processing apparatus, according to some example embodiments of the present disclosure.

FIG. 2 is a schematic block diagram illustrating an exposure process of a substrate processing apparatus, according to some example embodiments of the present disclosure.

FIG. 3 is a perspective view illustrating an example of a reticle pod used in an exposure process of a substrate processing apparatus, according to some example embodiments of the present disclosure.

FIG. 4 illustrates an extreme ultraviolet (EUV) exposure apparatus of FIG. 2.

FIG. 5 illustrates a mask inspection apparatus of FIG. 2.

FIG. 6 illustrates an ultraviolet (UV) exposure apparatus of FIG. 2.

FIG. 7 is a top-plan view of a UV exposure apparatus of FIG. 6 viewed in a first direction.

FIG. 8 is a top-plan view of a UV exposure apparatus of FIG. 6, according to some example embodiments of the present disclosure.

FIG. 9 is a top-plan view of a UV lamp in a substrate processing apparatus, according to some example embodiments of the present disclosure.

FIG. 10 is a top-plan view of a UV lamp in a substrate processing apparatus, according to some example embodiments of the present disclosure.

FIG. 11 is a top-plan view of a UV lamp in a substrate processing apparatus, according to some example embodiments of the present disclosure.

FIG. 12 is a top-plan view of a reticle illustrated in FIG. 3.

FIGS. 13 and 14 illustrate a process in which an oxide layer is formed on the reticle illustrated in FIG. 3.

FIG. 15 is a flowchart of a substrate processing method using a substrate processing apparatus, according to some example embodiments of the present disclosure.

FIGS. 16, 17, 18, 19, 20, 21, 22, 23, 24, 25, and 26 illustrate operations in a substrate processing method using a substrate processing apparatus, according to some example embodiments of the present disclosure.

FIG. 27 is a flowchart of a substrate processing method using a substrate processing apparatus, according to some example embodiments of the present disclosure.

FIGS. 28 and 29 illustrate operations in a substrate processing method using a substrate processing apparatus, according to some example embodiments of the present disclosure.

### DETAILED DESCRIPTION

Hereinafter, example embodiments of the present disclosure will be described in detail with reference to the drawings. The same elements in the drawings are denoted by the same reference numerals, and a redundant description thereof will be omitted for the sake of brevity.

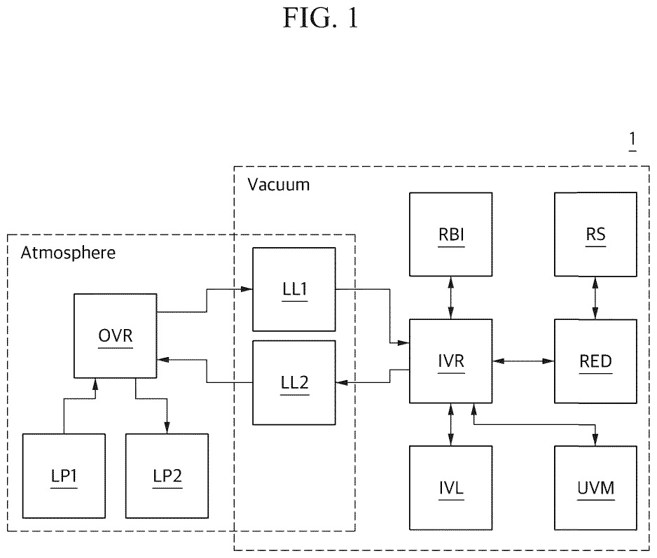

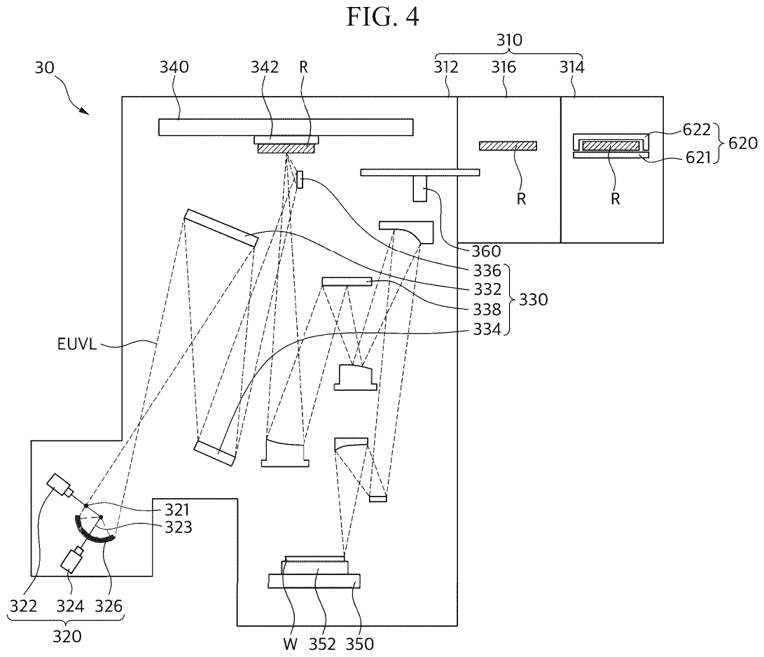

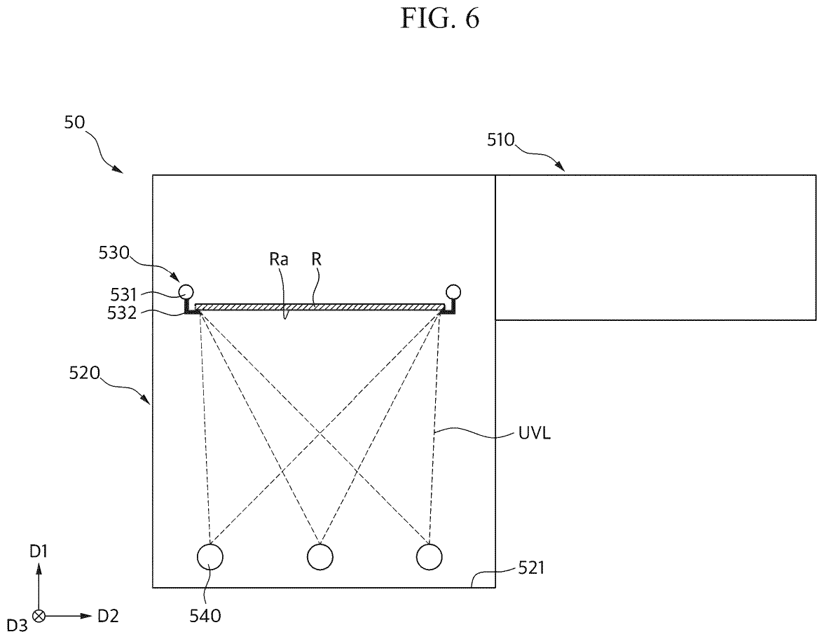

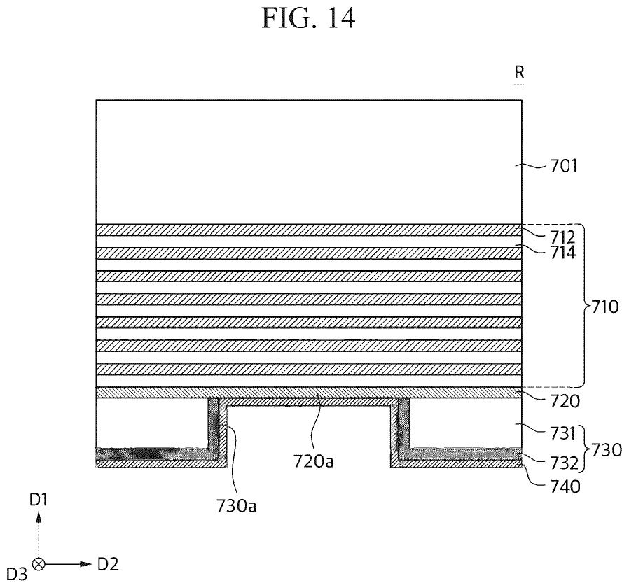

A substrate processing apparatus 1 (refer to FIG. 1) according to some example embodiments of the present disclosure may include an ultraviolet (UV) exposure apparatus 50 (refer to FIG. 6) that performs a UV exposure process on a reticle R (refer to FIG. 4) prior to an extreme ultraviolet (EUV) exposure process. A UV exposure apparatus 50 may remove an oxide layer 740 (refer to FIG. 14) formed on a main surface Ra (refer to FIG. 6) of the reticle R by irradiating the main surface Ra of the reticle R with a UV beam UVL (refer to FIG. 6).

Additionally, the substrate processing apparatus 1, according to some example embodiments of the present disclosure, may include a supporting portion 530 (refer to FIG. 6), that supports the reticle R in the UV exposure apparatus 50, such that the main surface Ra of the reticle R faces a UV lamp 540 (refer to FIG. 6), thereby enabling effective or desired UV beam irradiation of the reticle R.

FIG. 1 is a schematic block diagram illustrating different paths or routes taken by a reticle pod within the substrate processing apparatus 1, according to some example embodiments of the present disclosure. FIG. 1 is a block diagram illustrating a path taken by of a reticle pod when moved in the substrate processing apparatus 1 using an external transfer robot OVR and an internal transfer robot IVR.

Referring to FIG. 1, the substrate processing apparatus 1 may include a first and second load ports LP1 and LP2, the external transfer robot OVR, a first and second load locks LL1 and LL2, the internal transfer robot IVR, a mask storage device IVL, a mask inspection apparatus RBI, a rapid exchange device RED, an EUV exposure apparatus RS, and a UV exposure apparatus UVM.

According to some example embodiments, the first and second load ports LP1 and LP2 may provide a space to store the reticle pod. The external transfer robot OVR may be configured to load the reticle pod stored in the first load port LP1 and unload it to the first load lock LL1. In addition, the external transfer robot OVR may be configured to load the reticle pod stored in the second load lock LL2 and unload it to the second load port LP2. The arrows shown in FIG. 1 indicate example moving paths of the reticle pod. The external transfer robot OVR may be placed in an external mask transfer chamber according to some example embodiments. In this case, the first and second load ports LP1 and LP2 may be placed near or adjacent to an entrance of the external mask transfer chamber.

According to some example embodiments, internal and external parts of the first and second load ports LP1 and LP2 may be at atmospheric pressure. The external transfer robot OVR may be in an atmospheric pressure environment and load a reticle pod from the first load port LP1. The external transfer robot OVR may have at least one robotic arm, and may use the robotic arm to load a reticle pod from the first load port LP1 and unload the reticle pod to the first load lock LL1. In addition, the external transfer robot OVR may use the robotic arm to load a reticle pod from the second load lock LL2 and unload the reticle pod to the second load port LP2.

According to some example embodiments, the first and second load locks LL1 and LL2 may be switched between an atmospheric pressure state and vacuum state. The first and second load locks LL1 and LL2 may provide a space to house a reticle pod. The first load lock LL1 may house or receive a reticle pod, which has been exposed to atmospheric pressure, via the external transfer robot OVR, and evacuate air from an interior thereof while the reticle pod is housed (or located therein), and maintain a vacuum environment (e.g., 10⁻⁷ Torr or less) in first load lock LL1. Alternatively, the second load lock LL2 may house a reticle pod, which has been in a vacuum state, via the internal transfer robot IVR, and maintain the interior in which the reticle pod is housed in an atmospheric pressure state by drawing in air from outside. The internal transfer robot IVR may be placed in the mask transfer chamber, according to example embodiments. In this case, the first and second load locks LL1 and LL2 may be positioned near an entrance of the external mask transfer chamber.

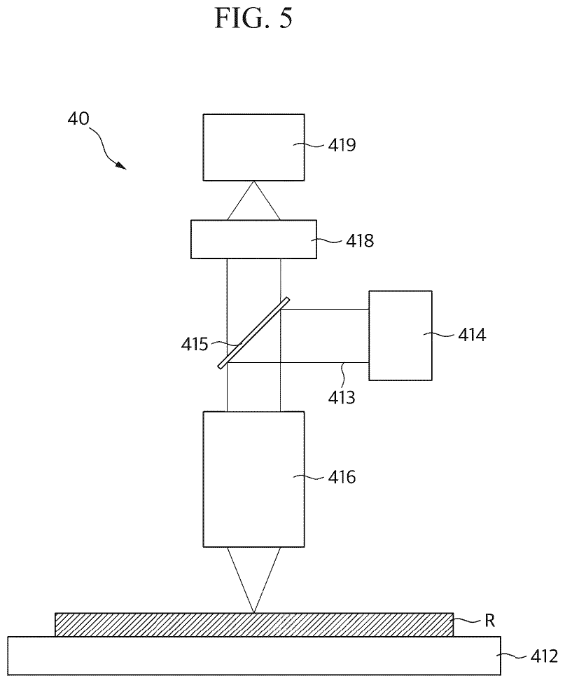

According to some example embodiments, the internal transfer robot IVR may be configured to load a reticle pod housed in the first load lock LL1 and transfer it to the mask inspection apparatus RBI. Also, the internal transfer robot IVR may be configured to load a reticle pod which has been inspected in the mask inspection apparatus RBI. According to some example embodiments, the internal transfer robot IVR may be configured to load a reticle pod housed in the mask storage device IVL and transfer it to the mask inspection apparatus RBI. According to some example embodiments, the internal transfer robot IVR may be configured to load a reticle pod that has been irradiated with a UV beam by the UV exposure apparatus UVM, and transfer it to the mask inspection apparatus RBI. A description of the mask inspection apparatus RBI will be provided with reference to FIG. 5.

According to some example embodiments, the internal transfer robot IVR may be configured to load a reticle pod that has been inspected in the mask inspection apparatus RBI, and transfer it to the mask storage device IVL. Also, the internal transfer robot IVR may be configured to load a reticle pod stored in the mask storage device IVL. According to some example embodiments, the internal transfer robot IVR may be configured to load a reticle pod housed in the first load lock LL1 and transfer it to the mask inspection apparatus RBI. According to some example embodiments, the internal transfer robot IVR may be configured to load a reticle pod that has been irradiated with an EUV beam by the EUV exposure apparatus RS, and transfer it to the mask inspection apparatus RBI. The mask inspection apparatus RBI may store the reticle pod. For example, the mask inspection apparatus RBI may be a reticle library in which different types of reticles are stored.

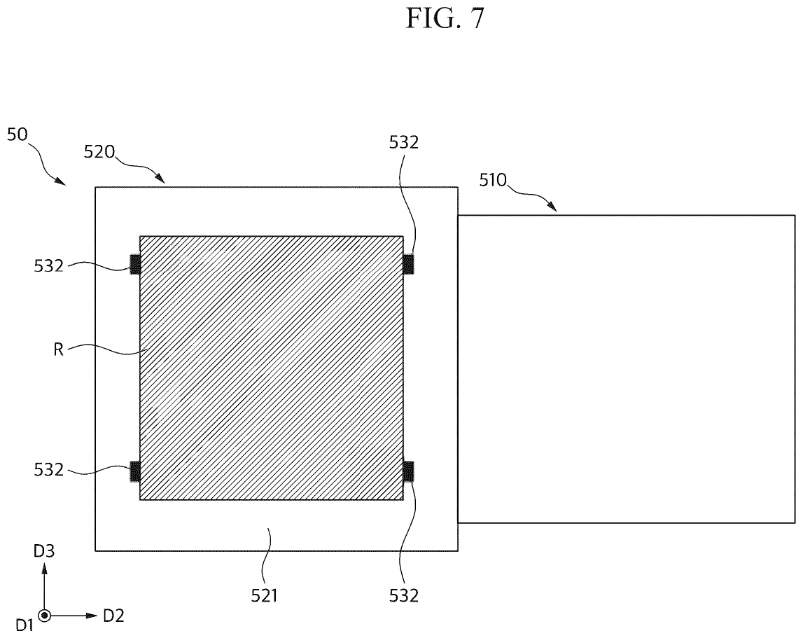

According to some example embodiments, the internal transfer robot IVR may be configured to load or pickup or otherwise receive a reticle pod stored in the mask storage device IVL and transfer it to the UV exposure apparatus UVM. Also, the internal transfer robot IVR may be configured to load or pickup or otherwise receive a reticle pod, which has been irradiated with a UV beam, from the UV exposure apparatus UVM. According to some example embodiments, the internal transfer robot IVR may be configured to load a reticle pod housed in the first load lock LL1, and transfer it to the UVE exposure apparatus UVM. According to some example embodiments, the internal transfer robot IVR may be configured to load, pickup or otherwise receive a reticle pod which has been inspected in the mask inspection apparatus RBI, and transfer it to the UV exposure apparatus UVM. A description of the UV exposure apparatus UVM will be provided with reference to FIGS. 6 and 7.

According to some example embodiments, the internal transfer robot IVR may be configured to load a reticle pod, which has been irradiated with a UV beam by the UV exposure apparatus UVM, and transfer it to the rapid exchange device RED. Also, the internal transfer robot IVR may be configured to load a reticle pod, which has been irradiated with an EUV beam in the EUV exposure apparatus RS, from the rapid exchange device RED. The internal transfer robot IVR may be configured to transfer a reticle pod housed in the mask storage device IVL, UV exposure apparatus UVM, and/or mask inspection apparatus RBI, to the rapid exchange device RED. However, the reticle of the reticle pod transferred to the rapid exchange device RED may be a reticle that has been irradiated with a UV beam. The rapid exchange device RED may promptly put a reticle pod into the EUV exposure apparatus RS or promptly take out a reticle pod from the EUV exposure apparatus RS. In other words, the rapid exchange device RED may minimize reticle exchange time between the EUV exposure apparatus RS and other components of the substrate processing apparatus 1. A description of the rapid exchange device RED will be provided with reference to FIG. 4.

According to some example embodiments, the internal transfer robot IVR may be configured to transfer a reticle pod, which has been irradiated with an EUV beam in the EUV exposure apparatus RS, to the second load lock LL2. The second load lock LL2 may house the reticle pod which has been in a vacuum state, and maintain the interior in which the reticle pod is housed in an atmospheric pressure state by drawing in air from outside. The external transfer robot OVR may be configured to load, pickup or otherwise receive a reticle pod, which has been in an atmospheric pressure state, from the second load lock LL2, and transfer it to the second load port LP2.

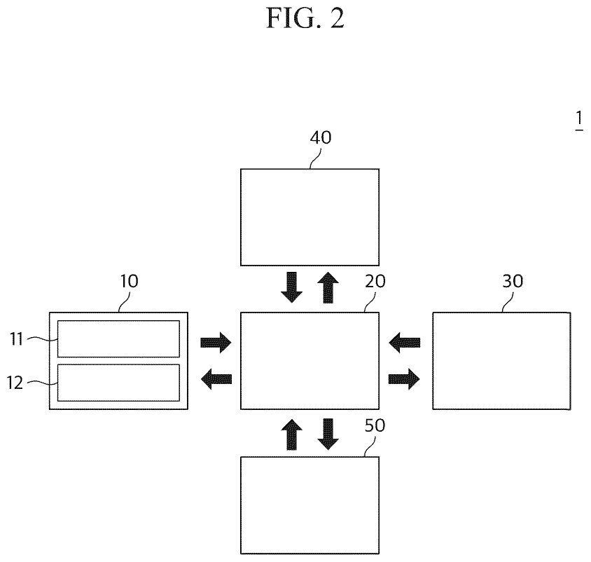

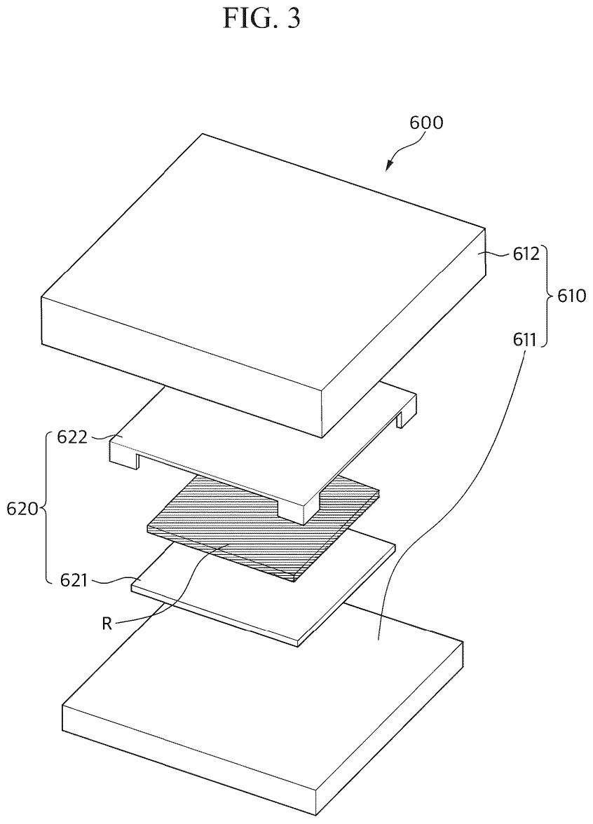

FIG. 2 is a schematic block diagram illustrating an exposure process of the substrate processing apparatus, according to some example embodiments of the present disclosure. FIG. 3 is a perspective view illustrating an example of a reticle pod used in an exposure process of the substrate processing apparatus according to some example embodiments of the present disclosure. FIG. 4 is a schematic drawing for describing an EUV exposure apparatus of FIG. 2. Hereinafter, a description will be provided with reference to FIGS. 2, 3, and 4.

According to some example embodiments, the substrate processing apparatus 1 may include a load lock assembly 10, an internal transfer robot 20, an EUV exposure apparatus 30, a mask inspection apparatus 40, and a UV exposure apparatus 50. The load lock assembly 10 may include a first load lock 11 and a second load lock 12. A first load lock 11 and a second load lock 12 shown in FIG. 2 may be same as or similar in some respects to the first load lock LL1 and the second load lock LL2 shown in FIG. 1. The internal transfer robot 20, EUV exposure apparatus 30, mask inspection apparatus 40, and UV exposure apparatus 50 may be same as or similar in some respects to the internal transfer robot IVR, EUV exposure apparatus RS, mask inspection apparatus RBI, and UV exposure apparatus UVM, respectively.

As described with reference to FIG. 1, the internal transfer robot 20 may be configured to transfer a reticle pod between the EUV exposure apparatus 30, mask inspection apparatus 40, and UV exposure apparatus 50.

Referring to FIG. 3, a reticle pod 600 may be formed to be a dual-pod. For example, the reticle pod 600 may include an outer pod 610 and an inner pod 620.

According to some example embodiments, the outer pod 610 may surround or enclose and thereby protect the inner pod 620. For example, the outer pod 610 may include an organic chemical polymer made of plastic or rubber. For example, the outer pod 610 may include a first base 611 and a first cover 612. The first base 611 may support the inner pod 620. The first cover 612 may cover the first base 611 and inner pod 620.

According to some example embodiments, the inner pod 620 may be placed in the outer pod 610. The inner pod 620 may store and protect the reticle R. The inner pod 620 may seal the reticle R. For example, the inner pod 620 may include a metal, such as iron, aluminum, tungsten, molybdenum, nickel, or an alloy thereof. For example, the inner pod 620 may include a second base 621 and a second cover 622. The second base 621 may support the reticle R. The second cover 622 may cover the second base 621 and the reticle R.

According to some example embodiments, the reticle R may be provided between the second base 621 and the second cover 622. The reticle R may be a photomask. The reticle R may include a base substrate and reflective layers on the base substrate.

According to some example embodiments, the outer pod 610 may be first separated from the inner pod 620 in an atmospheric pressure environment before being placed in or transferred to the load lock assembly 10, and the inner pod 620 may then be placed in or transferred to the load lock assembly 10 via the external transfer robot OVR (refer to FIG. 1). The reticle pod 600 transferred along the transfer paths illustrated using arrows in FIG. 2 may be the inner pod 620 with the outer pod 610 removed.

Referring to FIG. 4, the EUV exposure apparatus 30 may include an EUV exposure chamber 310, an EUV source 320, an optical system 330, a first reticle stage 340, and a substrate stage 350. A rapid exchange device 360 may move in and out of a main chamber 312, a first auxiliary chamber 314, and a second auxiliary chamber 316, outside the EUV exposure apparatus 30. The rapid exchange device 360 may be same as or similar in some respects to the rapid exchange device RED described with reference to FIG. 1.

According to some example embodiments, the EUV exposure chamber 310 may provide a space that separates a substrate W and the reticle R from outside. The EUV exposure chamber 310, as described with reference to FIG. 1, may operate under vacuum pressure. The EUV exposure chamber 310 may include the main chamber 312, the first auxiliary chamber 314, and the second auxiliary chamber 316. The main chamber 312 may house the EUV source 320, the optical system 330, the first reticle stage 340, and the substrate stage 350. The first auxiliary chamber 314 may be disposed to be spaced apart from the main chamber 312. The first auxiliary chamber 314 may temporarily store the inner pod 620 and the reticle R in the inner pod 620. As described above, the outer pod 610 may be separated from the inner pod 620, outside the load lock assembly 10, and the inner pod 620 may be provided or stored in the first auxiliary chamber 314. The second auxiliary chamber 316 may be disposed between the main chamber 312 and the first auxiliary chamber 314. The second auxiliary chamber 316 may connect the first auxiliary chamber 314 to the main chamber 312. The second auxiliary chamber 316 may store the reticle R temporarily, for example before being provided to the main chamber 312. The inner pod 620 may be separated from the reticle R in the first auxiliary chamber 314, and the reticle R may be provided in the second auxiliary chamber 316.

According to some example embodiments, the EUV source 320 may be placed on one side within the main chamber 312. The EUV source 320 may generate an EUV beam EUVL. The EUV beam EUVL may be a plasma beam. As an example, the EUV source 320 may include a source droplet generator 322, a first laser 324, and a collector mirror 326. The source droplet generator 322 may generate a source droplet 321. The source droplet 321 may include a liquid metal droplet of tin (Sn), xenon (Xe) gas, titanium (Ti), or lithium (Li). The first laser 324 may generate the EUV beam EUVL by emitting a first laser beam 323 to the source droplet 321. The first laser beam 323 may be a pump light of the EUV beam EUVL. The intensiveness of the EUV beam EUVL may be proportional to the intensiveness or power of the first laser beam 323. The collector mirror 326 may focus the EUV beam EUVL to the optical system 330. For example, the collector mirror 326 may include a concave mirror.

According to some example embodiments, the optical system 330 may be disposed between the first reticle stage 340 and the substrate stage 350. The optical system 330 may sequentially deliver the EUV beam EUVL to the reticle R and the substrate W. As an example, the optical system 330 may include a field facet mirror 332, a pupil facet mirror 334, a grazing mirror 336, and projection mirrors 338. The field facet mirror 332, pupil facet mirror 334, and grazing mirror 336 may be used as an illumination system that delivers the EUV beam EUVL to the reticle R. The field facet mirror 332 may reflect the EUV beam EUVL to the pupil facet mirror 334. The pupil facet mirror 334 may reflect the EUV beam to the reticle R. The field facet mirror 332 and the pupil facet mirror 334 may collimate the EUV beam EUVL. The grazing mirror 336 may be disposed between the pupil facet mirror 334 and the reticle R. The grazing mirror 336 may adjust a grazing incident angle of the EUV beam EUVL. The projection mirrors 338 may be used as projection objectives that deliver the EUV beam EUVL to the substrate W. The projection mirrors 338 may deliver the EUV beam EUVL to the substrate W.

According to some example embodiments, the first reticle stage 340 may be disposed in an upper side of the main chamber 312. The first reticle stage 340 may include a reticle chuck 342. The reticle chuck 342 may use an electrostatic voltage to electrostatically hold the reticle R. For example, the reticle R may be a reflective mask. A portion of the EUV beam EUVL directed to the reticle R may be reflected to the projection mirrors 338, and another portion of the EUV beam may be absorbed into the reticle R. The projection mirrors 338 may reflect a portion of the reflected EUV beam EUVL to the substrate W.

According to some example embodiments, the substrate stage 350 may be disposed in a lower side of the main chamber 312. The substrate stage 350 may include a substrate chuck 352. The substrate chuck 352 may store or secure the substrate W. The substrate chuck 352 may electrostatically hold or secure the substrate W. The substrate W may be exposed to the EUV beam EUVL. A photoresist on the substrate W may be partially exposed to light, based on a pattern of the reticle R.

According to some example embodiments, the rapid exchange device 360 may move in and out between the first reticle stage 340 and the first auxiliary chamber 314. The rapid exchange device 360 may replace the reticle R on the reticle chuck 342. The rapid exchange device 360 may transfer the reticle R between the reticle chuck 342 and the second auxiliary chamber 316.

At least one robotic arm may be provided inside or outside the first auxiliary chamber 314. The robotic arm may load or unload the inner pod 620 from or to the first auxiliary chamber 314. In the first auxiliary chamber 314, the robotic arm may separate the inner pod 620 from the reticle R to reveal the reticle R or combine the inner pod 620 to enclose the reticle R. Additionally, the robotic arm may transfer the reticle R between the first auxiliary chamber 314 and the second auxiliary chamber 316.

FIG. 5 is a schematic drawing of the mask inspection apparatus 40 of FIG. 2.

Referring to FIG. 5, the mask inspection apparatus 40 may include an optical spectroscopy apparatus. As an example, the mask inspection apparatus 40 may include a second reticle stage 412, a second laser 414, a half mirror 415, an objective lens 416, an eyepiece 418, and a photodetector 419. The second reticle stage 412 may store the reticle R. The second laser 414 may generate a second laser beam 413. The second laser beam 413 may include argon fluoride (ArF) ultraviolet light (e.g., 193 nanometer (nm)). The half mirror 415 may be disposed between the objective lens 416 and the eyepiece 418, and may reflect the second laser beam 413 to the objective lens 416. The objective lens 416 may deliver the second laser beam 413 to the reticle R and receive the second laser beam 413 reflected from the reticle R. The second laser beam 413 may pass through the half mirror 415 and the eyepiece 418, and be delivered to the photodetector 419. The photodetector 419 may detect the second laser beam 413 to detect and distinguish particle contamination on the reticle R. Alternatively, the photodetector 419 may detect and determine whether the reticle R is damaged.

FIG. 6 is a schematic drawing of the UV exposure apparatus 50 of FIG. 2. FIG. 7 is a top-plan view of the UV exposure apparatus 50 of FIG. 6 viewed in a first direction (from top to bottom in FIG. 6).

Referring to FIGS. 6 and 7, the UV exposure apparatus 50 may include a cover storage 510, a UV exposure chamber 520, a supporting portion 530, and a UV lamp 540.

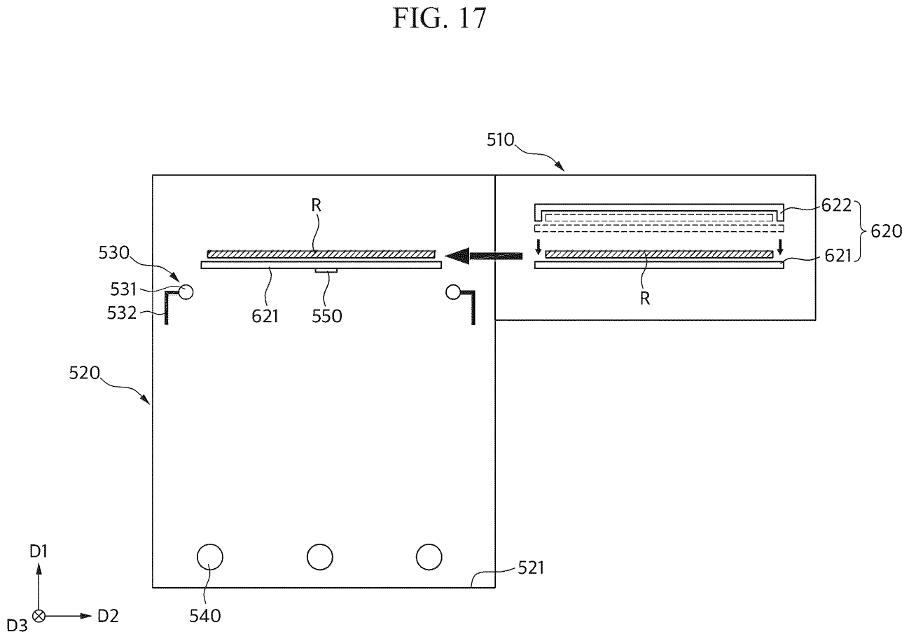

According to some example embodiments, the UV exposure chamber 520 may provide a space that separates the reticle R from the outside. The UV exposure chamber 520 may house the reticle R. The UV exposure chamber 520, as described with reference to FIG. 1, may operate under vacuum pressure. The cover storage 510 may be positioned on lateral side (or lateral part) of the UV exposure chamber 520 and connected to the UV exposure chamber 520. Here, the cover storage 510 may be placed at a level higher than that of the UV lamp 540, in a first direction (direction D1). As described below with reference to FIG. 17, the inner pod 620 which has been separated from the outer pod 610 may be brought into the cover storage 510 via the internal transfer robot 20 (refer to FIG. 2). A robotic arm configured to separate the second cover 622 from the second base 621 may be provided in the cover storage 510. The cover storage 510 may temporarily store the second cover 622 separated from the second base 621. The second base 621, on which the reticle R is seated, may be put into the UV exposure chamber 520.

According to some example embodiments, the UV exposure chamber 520 may house the supporting portion 530 and the UV lamp 540. In some example embodiments, the UV exposure chamber 520 is illustrated as having a quadrangular column shape with a quadrangle bottom surface. However, the UV exposure chamber 520, according to some example embodiments, may have a polygonal column shape with a polygonal bottom surface. In some example embodiments, the first direction (direction D1) is considered as a direction intersecting a bottom surface 521 of the UV exposure chamber 520. In addition, a second direction (direction D2) is considered as a direction intersecting the first direction (direction D1), as well as a direction in which the cover storage 510 is spaced apart from the UV exposure chamber 520. A third direction (direction D3) is considered as a direction intersecting the first direction (direction D1) and the second direction (direction D2).

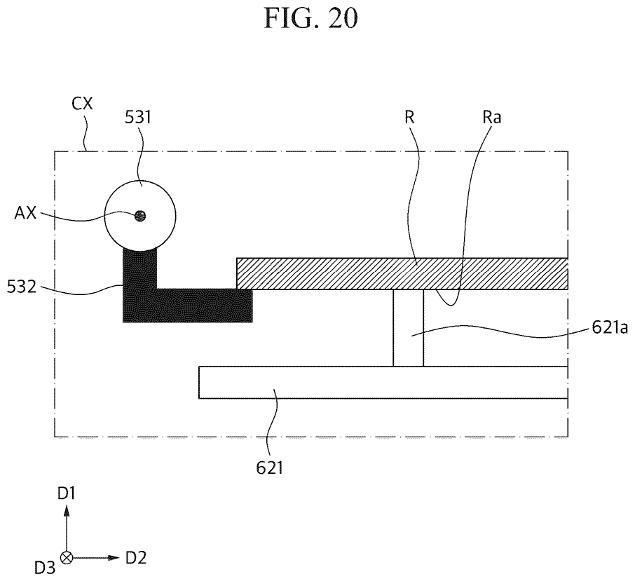

According to some example embodiments, the supporting portion 530 may be configured to support the reticle R in the UV exposure chamber 520. The supporting portion 530 may include a pivot 531 and a bracket 532. The pivot 531 may be disposed to be spaced apart from the UV lamp 540, in the first direction (direction D1) from the bottom surface 521 of the UV exposure chamber 520. The pivot 531 may be configured to rotate about a rotating axis AX (refer to FIG. 20) parallel to the third direction (direction D3). However, the pivot 531 may rotate about a rotating axis that crosses or intersects the first direction (direction D1) and tilted toward the third direction (direction D3). The bracket 532 may be configured to rotate about the rotating axis by being connected to the pivot 531, and support the reticle R. The bracket 532 may be in contact with an edge of the main surface Ra of the reticle R and support the reticle R so that the main surface Ra of the reticle R faces the UV lamp 540.

According to some example embodiments, the UV lamp 540 may be disposed to face the supporting portion 530 on the bottom surface 521 of the UV exposure chamber 520. The UV lamp 540 may be disposed closer to the bottom surface 521 of the UV exposure chamber 520 than the supporting portion 530, in the first direction (direction D1). The UV lamp 540 may be a device for carrying out a UV light exposure process to the reticle R. The UV lamp 540 may be installed to be aligned to face the main surface Ra of the reticle R and perform an exposure process on the main surface Ra. When the UV lamp 540 is aligned to face the main surface Ra of the reticle R, a UV beam emitted from the UV lamp 540 is incident in a direction intersecting the main surface Ra of the reticle R. In order to remove the oxide layer 740 (refer to FIG. 14) formed on the main surface Ra of the reticle R, it is beneficial to provide or deliver adequate energy to the oxide layer 740.

According to some example embodiments, the UV lamp 540 may generate and output a UV beam UVL corresponding to a wavelength of UV. In some example embodiments, the main surface Ra of the reticle R is a surface on which an absorption structure layer 730 is formed in reticle R, which is also a surface that is irradiated with an EUV beam during an EUV exposure process.

According to some example embodiments, the UV lamp 540 may remove an oxide layer formed on the main surface Ra of the reticle R by irradiating the main surface Ra of the reticle R with the UV beam UVL. The UV lamp 540 may direct the UV beam UVL for a sufficient, desired, or given amount of time to remove (for example, completely remove or remove a desired amount) the oxide layer formed on the main surface Ra of the reticle R. The high energy of the UV beam UVL may be transferred to the oxide layer and break the connection between molecules forming the oxide layer.

As shown in FIG. 7, more than one bracket 532, of the supporting portion 530, may be placed in the UV exposure chamber 520. Each of the brackets 532 may be configured to be in contact with an edge of the main surface Ra of the reticle R and support the reticle R. In some example embodiments, with reference to FIG. 7, although the brackets 532 are illustrated as being in contact with edges of the reticle R that are parallel to the third direction (direction D3), this is merely an example and is not limited thereto. According to some example embodiments, the brackets 532 may be configured to contact edges of the reticle R that are parallel with the second direction (direction D2), and support the reticle R.

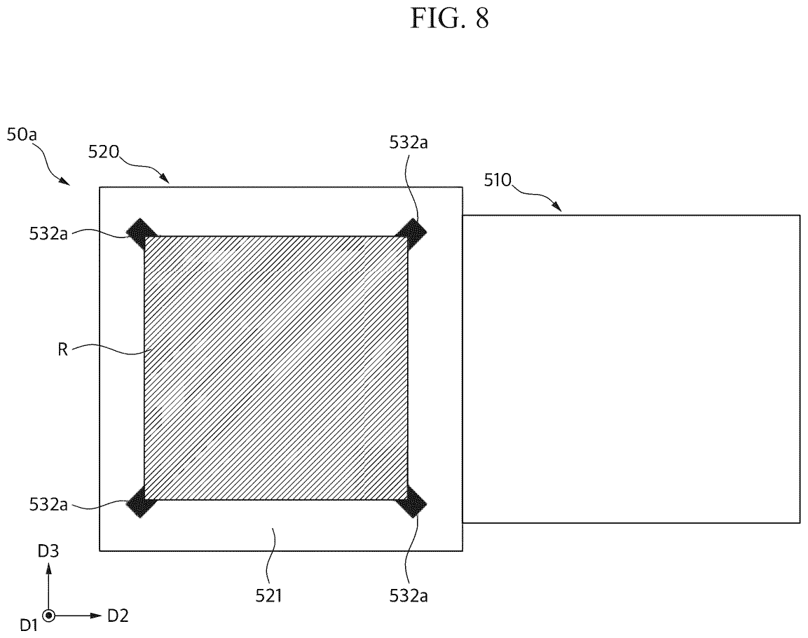

FIG. 8 is a top-plan view of a UV exposure apparatus 50a of the substrate processing apparatus according to some example embodiments of the present disclosure. The substrate processing apparatus shown in FIG. 8 is the same as or similar in some respects to the substrate processing apparatus shown in FIG. 7. As illustrated in FIG. 8, the substrate processing apparatus includes a bracket 532a that supports the reticle R at a different location. Accordingly, a description based on the difference between the substrate processing apparatuses shown in FIGS. 7 and 8 will be provided hereinafter.

As shown in FIG. 8, more than one bracket 532a may be placed in the UV exposure chamber 520. Each of the brackets 532a may be configured to contact a corner of the main surface Ra (refer to FIG. 6) of the reticle R and support the reticle R. In some example embodiments, the reticle R is shown as having a quadrangular surface. Therefore, each of the brackets 532a may be in contact with one of the four corners of the reticle R. However, in some example embodiments, the reticle R may have a polygonal surface, and each of the brackets may be in contact with one of the corners of the reticle R.

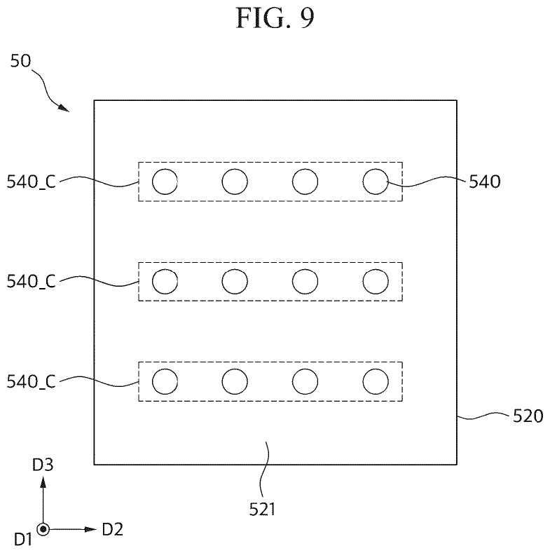

FIG. 9 is a top-plan view of the UV lamp 540 provided in the substrate processing apparatus, according to some example embodiments of the present disclosure.

Referring to FIG. 9, more than one UV lamp 540 may be disposed on the bottom surface 521 of the UV exposure chamber 520. A UV lamp assembly 540_C may include a plurality of UV lamps 540 which are aligned in the second direction (direction D2). More than one UV lamp assembly 540_C may be disposed on the bottom surface 521, and the UV lamp assemblies 540_C may be aligned in the third direction (direction D3). The plurality of UV lamps 540 disposed on the bottom surface 521 of the UV exposure chamber 520 may be aligned in a matrix arrangement.

In some example embodiment, although it is shown that the UV lamp assembly 540_C includes four UV lamps 540, the number of the UV lamps 540 in the UV lamp assembly 540_C is not limited thereto.

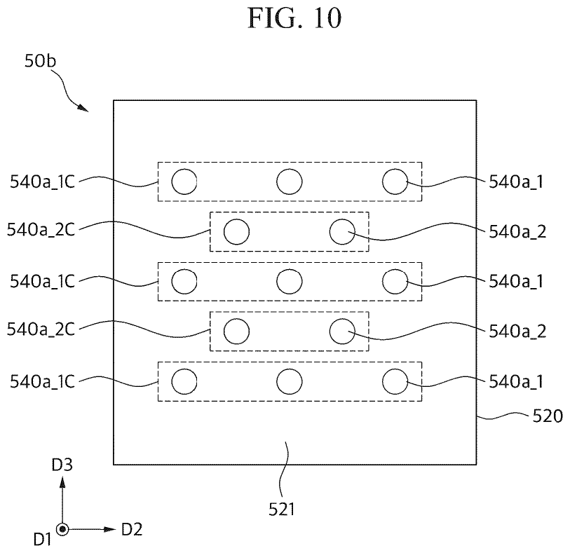

FIG. 10 is a top-plan view of UV lamps 540a_1 and 540a_2, placed in a UV exposure apparatus 50b of the substrate processing apparatus according to some example embodiments of the present disclosure.

Referring to FIG. 10, UV lamp assemblies 540a_1C and 540a_2C may be aligned or positioned on the bottom surface 521 of the UV exposure chamber 520 in the third direction (direction D3). More than one first UV lamp assembly 540a_1C may be disposed to be spaced apart from each other on the bottom surface 521 along the third direction (direction D3), and each of the second UV lamp assemblies 540a_2C may be disposed between a pair of adjacent first UV lamp assemblies 540a_1C. As illustrated in FIG. 10, the first UV lamp assemblies 540a_1C may be aligned with each other on the bottom surface 521, and the second UV lamp assemblies 540a_2C may be aligned with each other on the bottom surface 521.

According to some example embodiments, each of the first UV lamp assemblies 540a_1C may include a plurality of first UV lamps 540a_1 spaced apart and aligned in the second direction (direction D2), and each of the second UV lamp assemblies 540a_2C may include a plurality of second UV lamps 540a_2 spaced apart and aligned in the second direction (direction D2). Here, each of the plurality of second UV lamps 540a_2 may be disposed between a pair of adjacent first UV lamps 540a_1 among the plurality of first UV lamps 540a_1, and may be spaced apart from the plurality of first UV lamps 540a_1 in the third direction (direction D3).

In some example embodiments, the first UV lamp assembly 540a_1C includes three first UV lamps 540a_1, and the second UV lamp assembly 540a_2C includes two second UV lamps 540a_2. However, the number of first UV lamps 540a_1 and the second UV lamps 540a_2 in the first UV lamp assembly 540a_1C and the second UV lamp assembly 540a_2C, respectively, is not limited thereto.

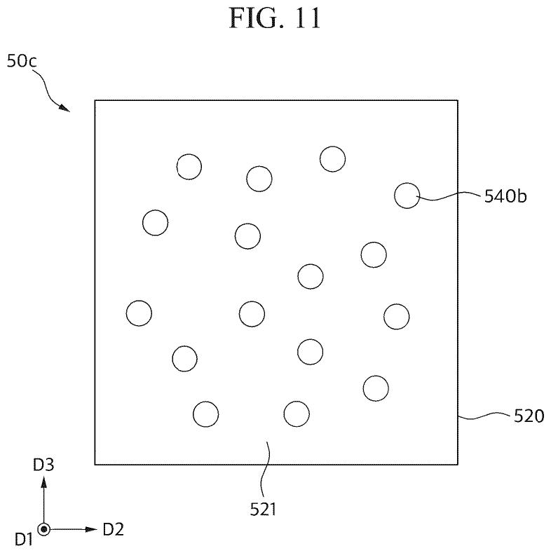

FIG. 11 is a top-plan view of a UV lamp 540b placed in a UV exposure apparatus 50c of the substrate processing apparatus according to some example embodiments of the present disclosure.

Referring to FIG. 11, more than one UV lamp 540b may be disposed on the bottom surface 521 of the UV exposure chamber 520. Here, the UV lamps 540b may be disposed in a random pattern or in an irregular arrangement on the bottom surface 521 of the UV exposure chamber 520. When UV lamps 540b are said to be disposed in random, it may indicate that at least one of the UV lamps 540b is disposed at a position staggered from the other UV lamps, in the second direction (direction D2) and the third direction (direction D3).

Although the example embodiment shows 16 UV lamps 540b disposed on the bottom surface 521, the number of the UV lamps 540b is not limited thereto.

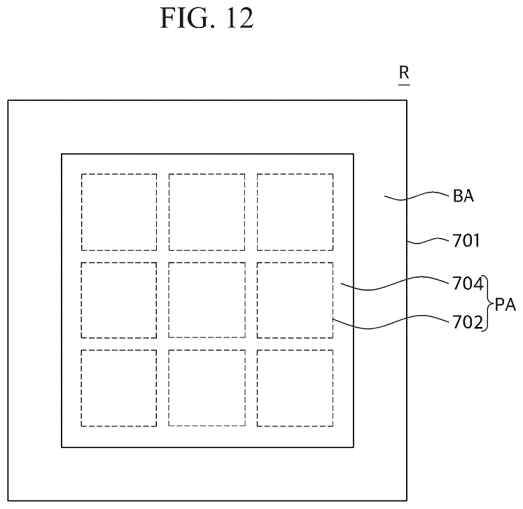

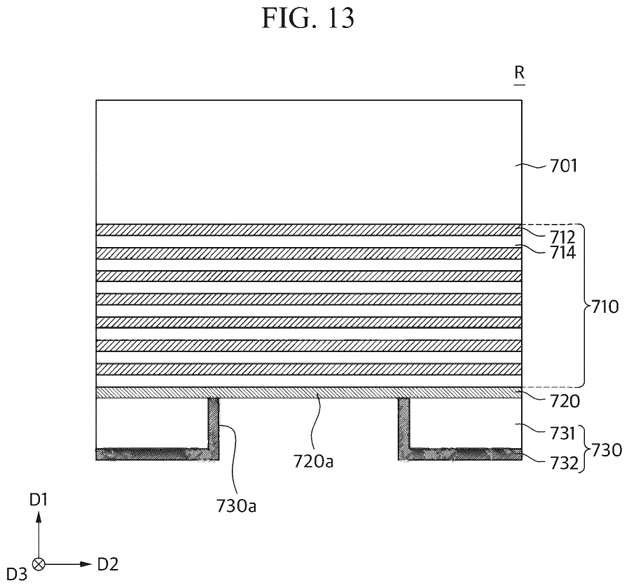

FIG. 12 is a top-plan view of the reticle illustrated in FIG. 2. FIGS. 13 and 14 illustrate a process in which an oxide layer is formed on the reticle shown in FIG. 2.

Referring to FIGS. 12, 13, and 14, the reticle R may include a base substrate 701, a reflective multi-layer 710, a capping layer 720, and the absorption structure layer 730. The base substrate 701, reflective multi-layer 710, and absorption structure layer 730 may have a flat quadrangular shape, as shown in FIG. 12. However, the base substrate 701, reflective multi-layer 710, capping layer 720, and absorption structure layer 730 may have a shape other than the flat quadrangular shape. Also, the reflective multi-layer 710, capping layer 720, and absorption structure layer 730 may have different sizes in the second direction (direction D2) and the third direction (direction D3). However, according to some example embodiments, the reflective multi-layer 710, capping layer 720, and absorption structure layer 730 may have substantially the same size in the second direction (direction D2) and the third direction (direction D3).

According to some example embodiments, the base substrate 701 may include a low thermal expansion material (LTEM). In other words, the base substrate 701 may include a material with low coefficient of thermal expansion (CTE). For example, the base substrate 701 may include glass, silicon (Si), quartz, and the like. However, the material the base substrate 701 is made of is not limited to the aforementioned materials.

Referring to FIG. 12, the base substrate 701 may include a patterned area PA, that includes or defines patterns to be transferred to a wafer, and a black border area BA around or surrounding the patterned area PA. The patterned area PA may include a main patterned area 702 and a sub-patterned area 704. The main patterned area 702 may be an area for transferring main patterns that form an integrated circuit on a chip area of the wafer W (of FIG. 4) and the sub-patterned area 704 may be an area for transferring sub-patterns on a scribe line area of the wafer W of (FIG. 4). The black border area BA may surround the patterned area PA when viewed in a plan view. One or more alignment marks for aligning the reticle R in the EUV exposure apparatus 30 of FIG. 4 and/or one or more identification marks for identifying the reticle R may be disposed on the black border area BA.

According to some example embodiments, the reflective multi-layer 710 may be disposed below the base substrate 701 in a direction opposite to the first direction (direction −D1, or a downward direction) from the base substrate 701. As shown in FIG. 6, the main surface Ra (refer to FIG. 6) of the reticle R is illustrated as facing the direction opposite to the first direction (direction −D1, or a downward direction). According to some example embodiments, the main surface Ra of the reticle R may be positioned to face the first direction (direction D1), and the reflective multi-layer 710 may also be disposed in the first direction (direction D1) from the base substrate 701.

According to some example embodiments, the reflective multi-layer 710 may reflect a beam, for example, an EUV beam, incident to the reflective multi-layer 710. The reflective multi-layer 710 may include a Bragg reflector. In the reticle R, according to some example embodiments, the reflective multi-layer 710 may have a multi-layer structure in which two types of material layers, 712 and 714, are alternately laminated to form a plurality of layers. In other words, the reflective multi-layer 710 may include a first material layer 712 and a second material layer 714, which are alternately laminated. Accordingly, the second material layer 714 may be disposed between a pair of adjacent first material layers 712, and alternatively, the first material layer 712 may be disposed between a pair of adjacent second material layers 714. The reticle R, according to some example embodiments, may include a laminated arrangement of 40 to 60 layers of each of the first material layer 712 and the second material layer 714. However, the number of layers of the first material layer 712 and the second material layer 714 is not limited to the above range.

According to some example embodiments, the first material layer 712 may be a layer with low refractive index and the second material layer 714 may be a layer with high refractive index. Accordingly, the second material layer 714 may have higher refractive index than that of the first material layer 712. For example, the first material layer 712 may include molybdenum (Mo) and the second material layer 714 may include silicon (Si). However, the material the first material layer 712 and the second material layer 714 is not limited to the above-mentioned materials. In the reticle R, according to some example embodiments, the first material layer 712, which is a layer with low refractive index, may be disposed on the upper most side of the reflective multi-layer 710 in the first direction (direction D1), and the second material layer 714, which is a layer with high refractive index, may be disposed on the lower most side of the reflective multi-layer 710.

According to some example embodiments, the capping layer 720 may be disposed in the direction opposite to the first direction (direction −D1, or a downward direction), from the reflective multi-layer 710. The capping layer 720 may be on the lowermost second material layer 714. The capping layer 720 may prevent, limit, or reduce damages on the reflective multi-layer 710, as well as oxidization of a surface of the reflective multi-layer 710. In the reticle R, according to some example embodiments, the capping layer 720, for example, may cover a surface of the second material layer 714 made of silicon (Si), and prevent, limit, or reduce oxidization of the second material layer 714. For example, the capping layer 720 may include ruthenium (Ru) or ruthenium oxide. However, the material the capping layer 720 is not limited thereto.

According to some example embodiments, the absorption structure layer 730 may include a first absorption layer 731 and a second absorption layer 732. The first absorption layer 731 may form a majority of the absorption structure layer 730. The first absorption layer 731 may be in contact with the capping layer 720. The first absorption layer 731 may include a material that absorbs light incident to the first absorption layer 731, such as an EUV beam. Accordingly, an EUV beam incident to the first absorption layer 731 may not be delivered or transmitted to the capping layer 720 or the reflective multi-layer 710. The first absorption layer 731 may include, for example, TaN, TaHf, TaHfN, TaBSi, TaBSiN, TaB, TaBN, TaSi, TaSiN, TaGe, TaGeN, TaZr, TaZrN, or a combination thereof. However, the material the first absorption layer 731 includes is not limited to the aforementioned materials.

According to some example embodiments, the second absorption layer 732 may be disposed on a surface of the first absorption layer 731. The second absorption layer 732 may be extended along the surface of the first absorption layer 731. The second absorption layer 732 may cover a surface of the first absorption layer 731 which is intersecting with the first direction (direction D1). The second absorption layer 732 may have a relatively smaller thickness when compared to the first absorption layer 731. The second absorption layer 732 may include TaBo, for example. However, the material the second absorption layer 732 includes is not limited to the aforementioned material.

According to some example embodiments, a portion of the capping layer 720 which is exposed through an opening 730a in the absorption structure layer 730 may be referred to as a exposed area 720a. The EUV beam incident on the exposed area 720a of the capping layer 720 may pass through the capping layer 720 and may be delivered or transmitted to the reflective multi-layer 710. Additionally, an EUV beam may be reflected by the reflective multi-layer 710 and directed to a wafer subject to an exposure process. Therefore, a pattern transferred on the wafer may correspond to a shape of the opening 730a in the absorption structure layer 730.

According to some example embodiments, the oxide layer 740 may be formed on a surface of the second absorption layer 732. The oxide layer 740 may also be formed on the exposed area 720a of the capping layer 720, which is exposed through the opening 730a of the absorption structure layer 730. As described with reference to FIGS. 1 through 3, the outer pod 610 may be separated from the inner pod 620 in an atmospheric pressure environment, before being loaded or put into the load lock assembly 10 (refer to FIG. 2), and the inner pod 620 may be put into the load lock assembly 10 using the external transfer robot OVR (refer to FIG. 1). During the process, the inner pod 620 may be exposed to atmosphere, and the oxygen in the atmosphere may permeate into or otherwise interact with the reticle R of the inner pod 620. As the oxygen in the atmosphere permeates into or interacts with the reticle R, the second absorption layer 732 and the capping layer 720 exposed through the opening 730a of the absorption structure layer 730 may cause an oxidation reaction with the oxygen. The oxide layer 740 is formed on a portion of the second absorption layer 732 and a portion of the capping layer 720, as a result of the oxidation reaction. Due to the oxide layer 740 formed, the light reflectance of the reticle R may decrease and cause errors in EUV exposure process as a result. Therefore, it is beneficial to remove or reduce the oxide layer 740 formed on the reticle R when the reticle R is exposed to the atmosphere before the EUV exposure process. When the oxide layer 740 is removed or reduced prior to the EUV exposure process, the reticle R may be able to maintain or have the desired or designed light reflectance during the EUV exposure process using the reticle R.

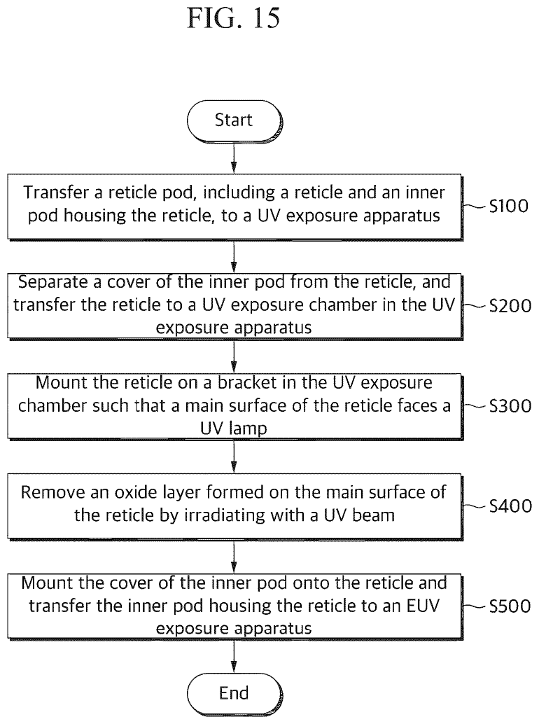

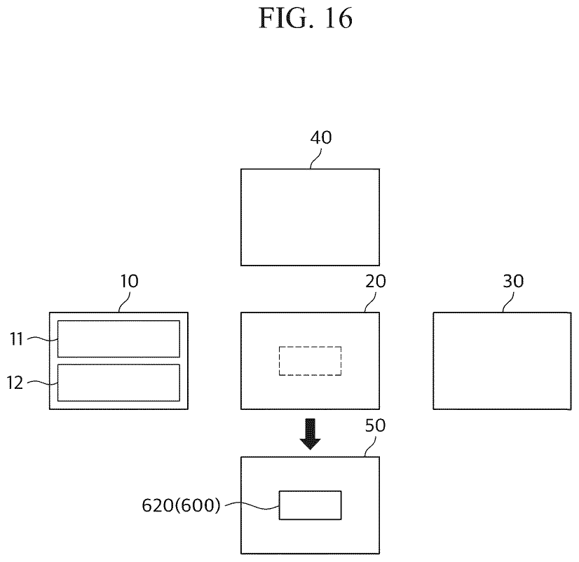

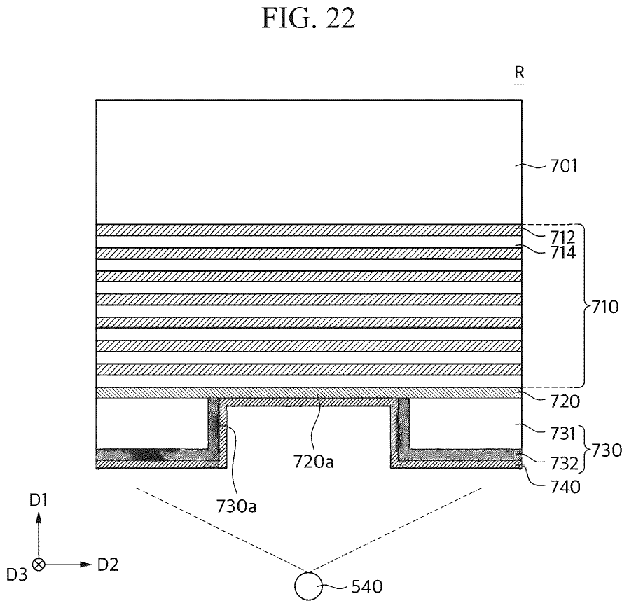

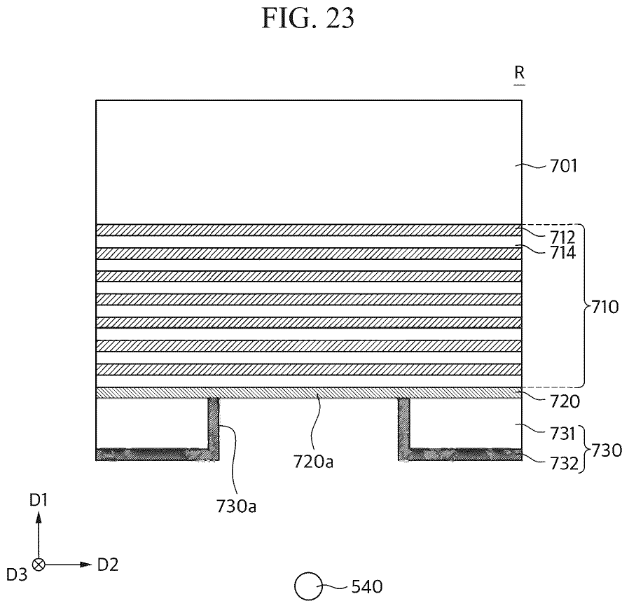

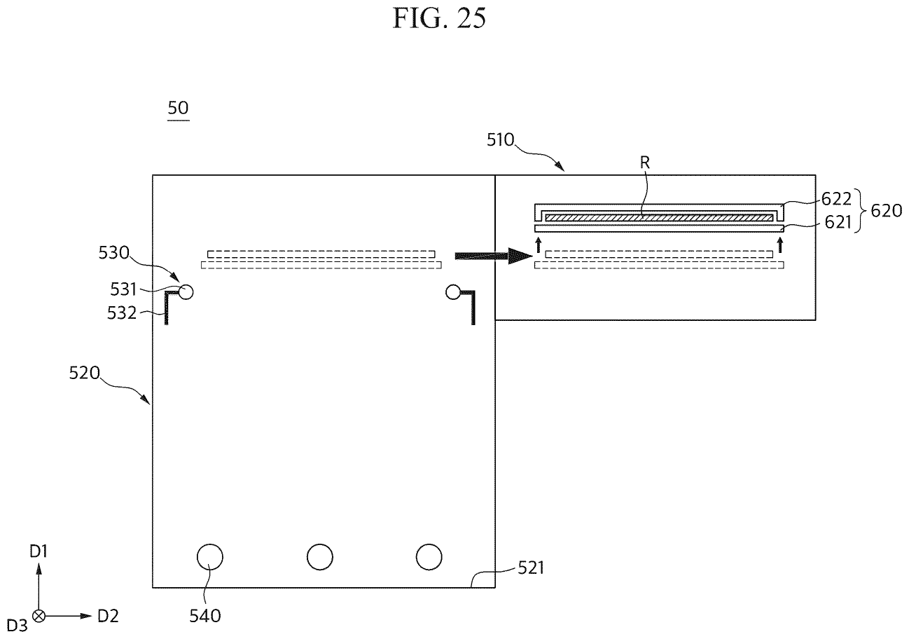

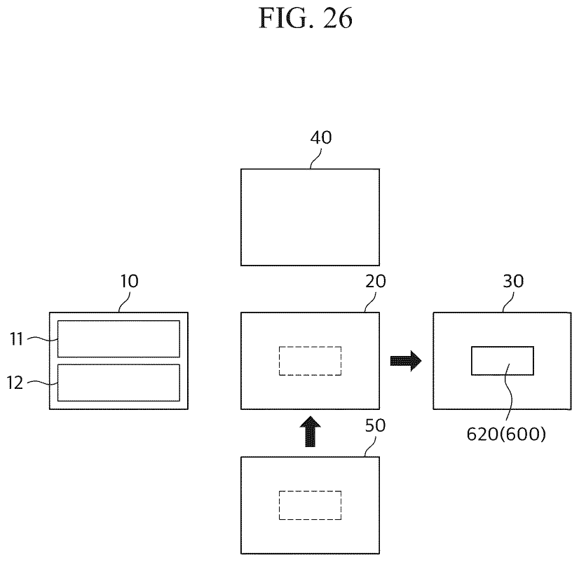

FIG. 15 is a flowchart for describing the substrate processing method using the substrate processing apparatus according to some example embodiments of the present disclosure. FIGS. 16 through 26 illustrate operations in the substrate processing method using the substrate processing apparatus, according to some example embodiments of the present disclosure. It is understood that additional operations can be provided before, during, and after the operations in FIG. 15, and some of the operations described below can be replaced or eliminated, for additional embodiments of the method. The order of the operations/processes may be interchangeable, or two or more operations can be performed simultaneously.

A control unit may be installed inside substrate processing apparatus 1 or may be external to the substrate processing apparatus 1 and may be operationally connected thereto. The control unit may give an instruction or control operations of the components of the substrate processing apparatus 1. The control unit may be configured to control operations of the first and second load locks 11 and 12, internal transfer robot 20, EUV exposure apparatus 30, mask inspection apparatus 40, and UV exposure apparatus 50. Additionally, the control unit may be configured to control operations of the first and second load ports LP1 and LP2 (refer to FIG. 1), external transfer robot OVR (refer to FIG. 1), mask storage device IVL (refer to FIG. 1), and rapid exchange device RED (refer to FIG. 1). In the substrate processing method described below, operations of the components may be controlled based on instructions from the control unit. The control unit may be implemented as hardware, firmware, software, or a combination thereof. For example, the control unit may be a computing device, such as a workstation computer, desktop computer, laptop computer, and tablet computer. For example, the control unit may include a memory, such as read-only memory (ROM) and random-access memory (RAM), and a processor configured to carry out a predetermined computation and algorithm. Also, the control unit may include a receiver and transmitter for receiving and transmitting electrical signals.

Referring to FIG. 16, together with FIG. 15, the substrate processing method, according to some example embodiments, may include operation S100 in which the reticle pod 600 including the reticle R and the inner pod 620 housing the reticle R is transferred to the UV exposure apparatus 50. The internal transfer robot 20 may receive the reticle pod 600 and transfer the reticle pod 600 to the UV exposure apparatus 50. Here, the reticle pod 600 that has been received by the internal transfer robot 20 may have been loaded or transferred from the mask storage device IVL (refer to FIG. 1), first load lock 11, or mask inspection apparatus 40.

Referring to FIG. 17, together with FIG. 15, the substrate processing method may include operation S200 in which the second cover 622 of the inner pod 620 is separated from the second base 621 to reveal the reticle R, and the reticle R is transferred to the UV exposure chamber 520 in the UV exposure apparatus 50. The second cover 622 of the inner pod 620 may be separated from the reticle R inside the cover storage 510. Here, a robotic arm may be provided in the cover storage 510, and the robotic arm may remove the second cover 622 which has been covering the second base 621 and the reticle R. The second cover 622 may be removed from the reticle R in various ways according to some example embodiments. For example, a distancing space or gap may be formed between an outer part of the second base 621 and a protruding part of the second cover 622, and when a supporting object is inserted into the distancing space or gap, and the second base 621 moves downward, and the second cover 622 may get separated from the reticle R and the second base 621. The method of separating the second cover 622 from the second base 621 and the reticle R is not limited to the method described above.

According to some example embodiments, the separated second cover 622 may be temporarily stored in the cover storage 510. Then, the second base 621 that houses or supports the reticle R may be put into the UV exposure chamber 520 from the cover storage 510. For example, a transfer robot that moves in and out of the cover storage 510 and UV exposure chamber 520 may be placed inside the UV exposure apparatus 50, and the transfer robot may transfer the second base 621, that houses or supports the reticle R, from the cover storage 510 to the UV exposure chamber 520.

According to some example embodiments, the second base 621 put into the UV exposure chamber 520 may be seated onto a driving unit 550 which has been standing by in the UV exposure chamber 520. The driving unit 550 may be a lifting robot, placed in the UV exposure chamber 520 and configured to move along the first to third directions (directions D1 to D3).

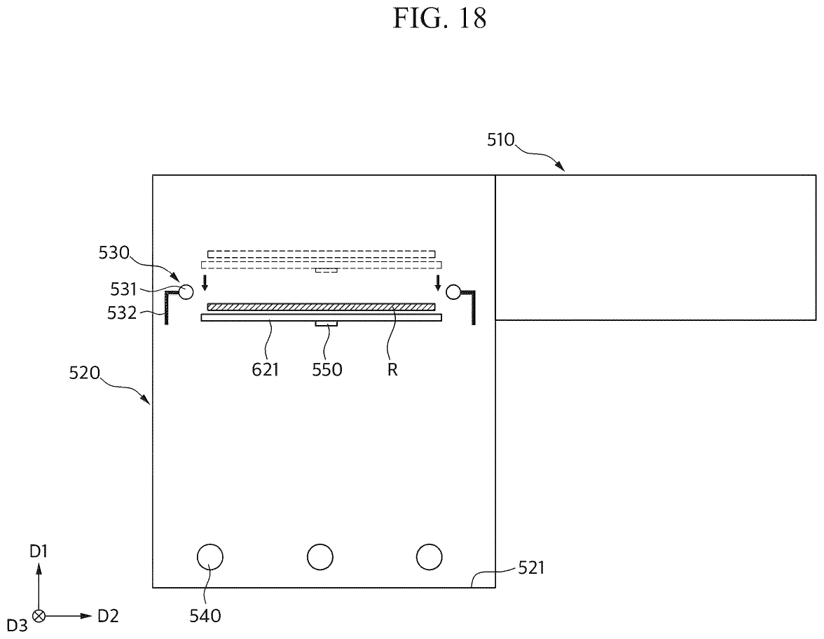

Referring to FIGS. 18, 19, and 20, together with FIG. 15, the substrate processing method may include operation S300 in which the reticle R is seated onto the bracket 532 in the UV exposure chamber 520 such that the main surface Ra of the reticle R faces the UV lamp 540. First, the driving unit 550 may move towards the supporting portion 530 in the direction opposite to the first direction (direction −D1, or a downward direction). The driving unit 550 may be able to move until the reticle R is positioned below the pivot 531 of the supporting portion 530, in the first direction (direction D1).

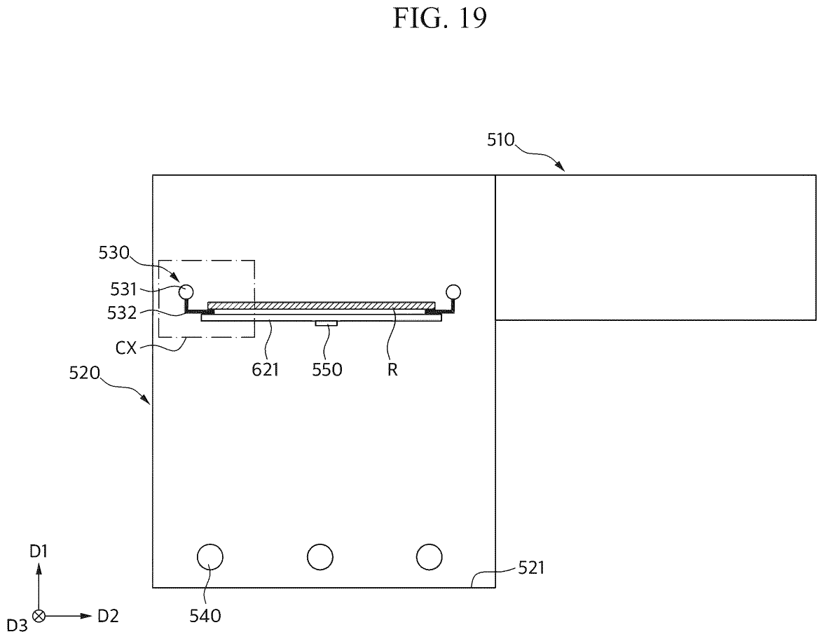

FIG. 20 is an enlarged view of the CX region of FIG. 19. As shown in FIGS. 19 and 20, the driving unit 550 will halt when the reticle R is positioned lower than the pivot 531. The pivot 531 may be configured to rotate about the rotating axis AX in the third direction (direction D3), and the bracket 532 may be configured to rotate together with the rotating pivot 531 by being connected to the pivot 531. When the reticle R is positioned lower than the pivot 531 in the first direction (direction D1), the bracket 532 will be in contact with the reticle R as it rotates together with the pivot 531. According to some example embodiments, the supporting portion 530 may be include a bracket that rotates without the pivot 531.

As shown in FIG. 20, a supporting pillar 621a may be formed on an upper surface of the second base 621, and the supporting pillar 621a may support the reticle R from below, for example, contact the main surface Ra. Accordingly, the reticle R may not be in direct contact with the second base 621, and a distancing space may be formed between the reticle R and the second base 621. The bracket 532 may rotate within the distancing space and contact with the reticle R. When the bracket 532 supports the reticle R from below, the pivot 531 may stop rotating and be fixed. Here, the main surface Ra of the reticle R supported by the bracket 532 may face the bottom surface 521 of the UV exposure chamber 520 in which the UV lamp 540 is placed.

According to some example embodiments, by providing the supporting portion 530 configured to support the reticle R in the UV exposure chamber 520, the reticle R may be aligned more effectively for UV beam UVL irradiation. By providing the bracket 532 which can rotate, the second base 621 may be removed from the reticle R more easily.

Then, according to some example embodiments, the driving unit 550 while supporting only the second base 621 moves out of a range of the UV beam of the UV lamp 540.

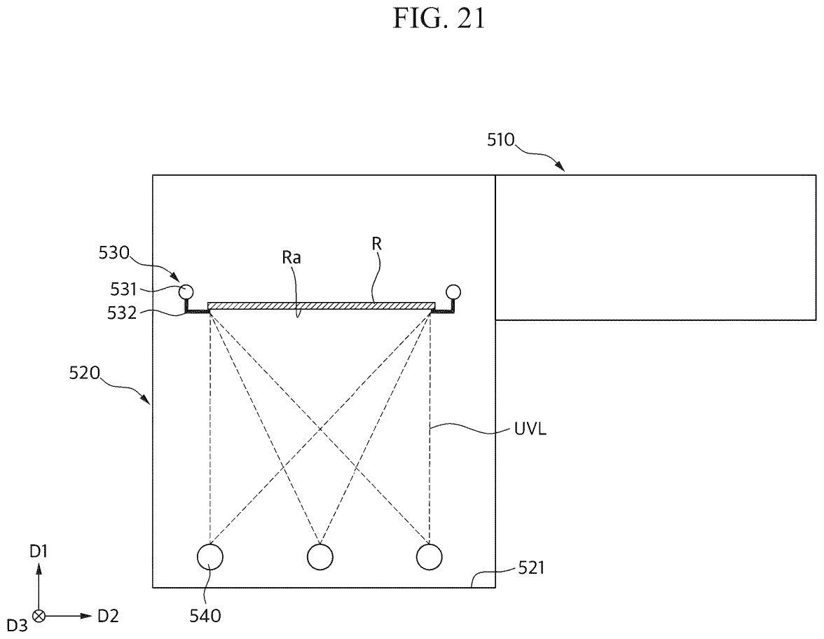

Referring to FIGS. 21, 22 and 23, together with FIG. 15, the substrate processing method may include operation S400 in which the oxide layer 740 formed on the main surface Ra of the reticle R is removed or reduced by irradiating with a UV beam.

As shown in FIG. 21, the UV lamp 540 may be aligned to face the main surface Ra of the reticle R. The UV lamp 540 may aim the UV beam UVL so that a majority of the UV beam UVL is incident in a direction intersecting the main surface Ra of the reticle R. Then, the UV lamp 540 may direct the UV beam UVL to the main surface Ra of the reticle R and the UV beam UVL may be incident on the main surface Ra. The oxide layer 740 on the second absorption layer 732 and the oxide layer 740 in the opening 730a of the absorption structure layer 730 are irradiated with the UV beam UVL. The high energy of the UV beam UVL may be transferred to the oxide layer 740 and break the connection between the molecules forming the oxide layer 740. The UV lamp 540 may direct the UV beam UVL to the reticle R for a sufficient, desired, or given amount of time until the oxide layer 740 is removed, for example, completely or by a desired amount. Once the sufficient, desired, or given amount of time has elapsed, the UV lamp 540 stops irradiation of the UV beam UVL.

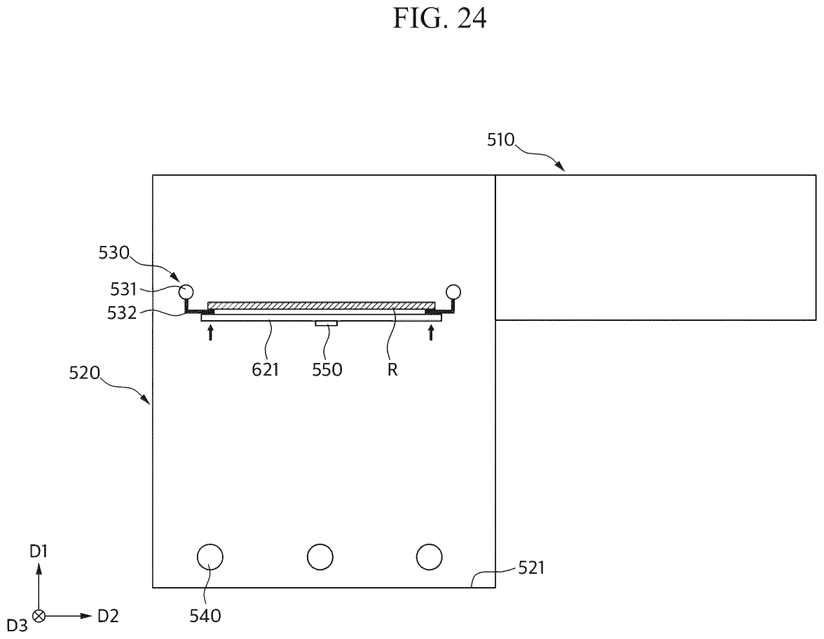

Referring to FIGS. 24, 25, and 26, together with FIG. 15, the substrate processing method may include operation S500 in which the second cover 622 of the inner pod 620 is mounted on the reticle R, and the inner pod 620 housing the reticle R is transferred to the EUV exposure apparatus 30.

First, the driving unit 550 that has been supporting the second base 621 is positioned below the bracket 532. Then, the series of processes described with reference to FIGS. 18 through 20 may be carried out in the reverse order. The supporting pillar 621a supports the main surface Ra of the reticle R from below, and the pivot 531 which has been fixed rotates again together with the bracket 532. The bracket 532 rotates towards the outer side of the UV exposure chamber 520, and the driving unit 550 moves in the first direction (direction D1) while supporting the second base 621 from below. The driving unit 550 moves until the second base 621 is positioned above the pivot 531, in the first direction (direction D1). Then, the second base 621 housing the reticle R moves to the cover storage 510 from the UV exposure chamber 520. The second cover 622 may be mounted again on the second base 621 that has been moved to the cover storage 510.

Then, the internal transfer robot 20 loads the reticle pod 600 from the UV exposure apparatus 50 and transfers it to the EUV exposure apparatus 30. The oxide layer of the reticle R in the reticle pod 600 transferred to the EUV exposure apparatus 30 may have been removed, for example, completely or by a desired amount, by UV beam irradiation.

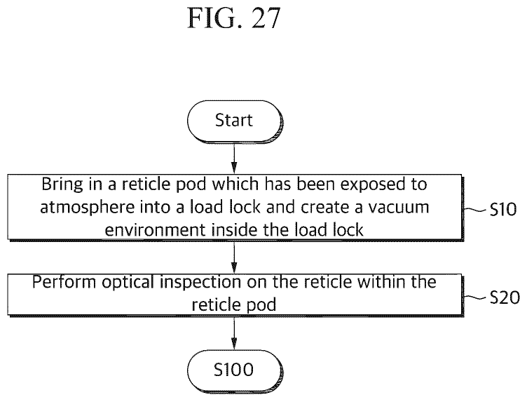

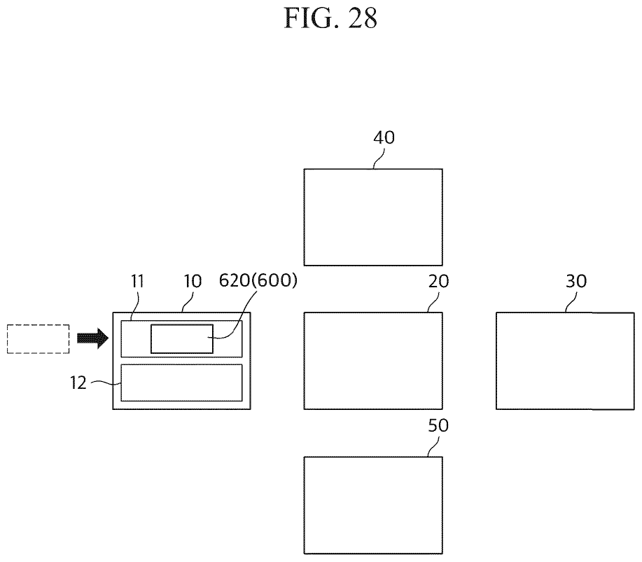

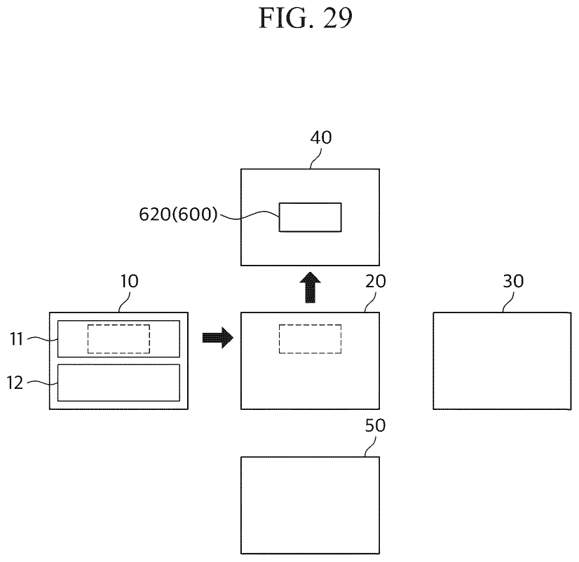

FIG. 27 is a flowchart for describing a substrate processing method using the substrate processing device according to some example embodiments of the present disclosure. FIGS. 28 and 29 illustrate operations in the exposure process using the substrate processing apparatus, according to some example embodiments of the present disclosure. It is understood that additional operations can be provided before, during, and after the operations in FIG. 27, and some of the operations described below can be replaced or eliminated, for additional embodiments of the method. The order of the operations/processes may be interchangeable, or two or more operations can be performed simultaneously.

Referring to FIG. 28, together with FIG. 27, the substrate processing method may include operation S10 in which the reticle pod 600 which has been exposed to atmosphere is brought into (or is received by) a load lock (the first load lock 11, for example), and a vacuum environment is created within the load lock (the first load lock 11, for example). The external transfer robot OVR (refer to FIG. 1) may bring in the reticle pod 600 which has been in an atmospheric pressure environment to the first load lock 11. Here, the reticle pod 600 may be the inner pod 620 with the outer pod 610 removed. After the reticle pod 600 is brought into the first load lock 11, the interior of the load lock may still be at atmospheric pressure.

Then, the first load lock 11, after housing the reticle pod 600 which has been exposed to atmospheric pressure, may evacuate air from its interior in which the reticle pod 600 is housed, and create and maintain a vacuum environment in the interior thereof.

Referring to FIG. 29, together with FIG. 27, the substrate processing method may include operation S20, in which optical inspection of the reticle R in the reticle pod 600 is carried out. The internal transfer robot 20 may load the reticle pod 600 housed in the first load lock 11 and transfer it to the mask inspection apparatus 40. The optical inspection of the reticle of the reticle pod 600 may be carried out in the mask inspection apparatus 40.

Then, the substrate processing method using the substrate processing apparatus performs the series of operations, from operation S100 to operation S500, as shown in FIG. 15. Accordingly, the reticle being irradiated with a UV beam in the UV exposure apparatus 50 may be a reticle on which optical inspection has been completed in the mask inspection apparatus 40.

According to some example embodiments, a substrate processing apparatus may include a UV exposure apparatus that performs a UV exposure process on a reticle prior to an EUV exposure process. The UV exposure apparatus may remove an oxide layer formed on a main surface of the reticle by irradiating the main surface of the reticle with a UV beam.

According to some example embodiments, a substrate processing apparatus may also include a supporting portion that supports the reticle such that the main surface of the reticle faces a UV lamp in the UV exposure apparatus, thereby enabling effective UV beam irradiation of the reticle.

While several example embodiments have been provided in the present disclosure, it should be understood that the disclosed systems and methods might be embodied in many other forms without departing from the spirit or scope of the present disclosure. The examples embodiments disclosed herein are to be considered as illustrative and not restrictive, and the intention is not to be limited to the details given herein. For example, the various elements or components may be combined or integrated in another system or certain features may be omitted, or not implemented.

What is claimed is:

1. A substrate processing apparatus comprising:
an ultraviolet (UV) exposure apparatus configured to irradiate a reticle with a UV beam; and
an extreme ultraviolet (EUV) exposure apparatus configured to irradiate the reticle, which has been irradiated with the UV beam by the UV exposure apparatus, with an EUV beam,
wherein the UV exposure apparatus comprises,
a UV exposure chamber configured to house the reticle;
a supporting portion configured to support the reticle in the UV exposure chamber; and
a UV lamp on a bottom surface of the UV exposure chamber and facing the supporting portion in a first direction that intersects the bottom surface,
wherein the UV lamp is configured to irradiate the reticle with UV beams to remove an oxide layer on a surface of the reticle.

2. The substrate processing apparatus of claim 1, wherein the UV lamp is aligned to face a main surface of the reticle supported by the supporting portion.

3. The substrate processing apparatus of claim 1, wherein the UV lamp is closer to the bottom surface of the UV exposure chamber than the supporting portion in the first direction.

4. The substrate processing apparatus of claim 1, wherein the supporting portion comprises:
a pivot configured to rotate about a rotating axis in a direction intersecting the first direction; and
a bracket connected to the pivot and configured to rotate about the rotating axis, the bracket contacting the reticle.

5. The substrate processing apparatus of claim 4, wherein the bracket is configured to contact an edge of a main surface of the reticle.

6. The substrate processing apparatus of claim 4, wherein the bracket is configured to contact a corner of a main surface of the reticle.

7. The substrate processing apparatus of claim 1, wherein a plurality of UV lamps are on the bottom surface of the UV exposure chamber, the plurality of UV lamps including the UV lamp, and
the plurality of UV lamps are in a matrix arrangement.

8. The substrate processing apparatus of claim 1, wherein the UV exposure apparatus includes a plurality of UV lamps, the plurality of UV lamps including the UV lamp, and
the plurality of UV lamps comprise,
a plurality of first UV lamps spaced apart in a second direction intersecting the first direction; and
a plurality of second UV lamps between a pair of adjacent first UV lamps of the plurality of first UV lamps in the second direction, and spaced apart from the plurality of first UV lamps in a third direction intersecting the second direction.

9. The substrate processing apparatus of claim 1, wherein a plurality of UV lamps are on the bottom surface of the UV exposure chamber, the plurality of UV lamps including the UV lamp, and
the plurality of UV lamps are in a random pattern.

10. The substrate processing apparatus of claim 1, wherein the UV lamp is configured to irradiate the reticle with the UV beam to completely remove the oxide layer on the reticle.

11. A substrate processing apparatus, comprising:
an ultraviolet (UV) exposure apparatus configured to irradiate a reticle pod with a UV beam, the reticle pod comprising a reticle, a base configured to support the reticle, and a cover configured to cover the reticle on the base; and
an extreme ultraviolet (EUV) exposure apparatus configured to perform an EUV exposure process on the reticle pod which had been irradiated with the UV beam by the UV exposure apparatus,
wherein the UV exposure apparatus comprises,
a cover storage configured to remove the cover of the reticle pod;
a UV exposure chamber configured to house the reticle pod with the cover removed;
a UV lamp on a bottom surface of the UV exposure chamber;
a pivot spaced apart from the UV lamp in a first direction intersecting the bottom surface, and configured to rotate about a rotating axis in a direction intersecting the first direction; and
a bracket connected to the pivot and configured to rotate about the rotating axis, the bracket contacting the reticle of the reticle pod,
wherein the UV lamp is configured to irradiate a main surface of the reticle with the UV beam to remove an oxide layer on the main surface of the reticle.

12. The substrate processing apparatus of claim 11, further comprising a mask inspection apparatus configured to perform optical inspection on the reticle,
wherein the UV exposure apparatus is configured to irradiate the reticle, on which the optical inspection has been performed, with the UV beam.

13. The substrate processing apparatus of claim 11, wherein the UV exposure apparatus further comprises a driving unit configured to move the reticle pod, with the cover removed, toward the bracket in the first direction within the UV exposure chamber.

14. The substrate processing apparatus of claim 11, wherein the bracket is configured to rotate together with the pivot and contact the reticle when the reticle is positioned below the pivot in the first direction.

15. The substrate processing apparatus of claim 11, wherein the EUV exposure apparatus is configured to irradiate the main surface of the reticle, from which the oxide layer has been removed, with an EUV beam.

16. The substrate processing apparatus of claim 11, further comprising a mask storage device configured to store the reticle pod which has been irradiated with the UV beam in the UV exposure apparatus.

17. The substrate processing apparatus of claim 11, wherein the UV lamp irradiates with the UV beam in a direction that intersects the main surface of the reticle.

18. The substrate processing apparatus of claim 11, wherein the cover storage is at a lateral part of the UV exposure chamber and connected to the UV exposure chamber, and
the cover storage is at a level higher than a level of the UV lamp in the first direction.

19. A substrate processing apparatus configured to perform an exposure process on a reticle pod comprising a reticle, a base configured to support the reticle, and a cover configured to cover the reticle on the base, the substrate processing apparatus comprising:
a load lock configured to receive the reticle pod which has been exposed to atmosphere and create a vacuum environment in the load lock after receiving the reticle pod;
a mask inspection apparatus configured to perform optical inspection on the reticle of the reticle pod;
an ultraviolet (UV) exposure apparatus configured to irradiate the reticle, on which the optical inspection has been performed, with a UV beam;
an extreme ultraviolet (EUV) exposure apparatus configured to perform an EUV exposure process on the reticle which has been irradiated with the UV beam in the UV exposure apparatus; and
a transfer robot configured to transfer the reticle pod between the load lock, the mask inspection apparatus, the UV exposure apparatus, and the EUV exposure apparatus,
wherein the UV exposure apparatus comprises,
a cover storage configured to remove the cover of the reticle pod received from the transfer robot;
a UV exposure chamber configured to house the reticle pod with the cover removed;
a supporting portion configured to support the reticle of the reticle pod in the UV exposure chamber; and
a UV lamp spaced apart from the supporting portion in a first direction intersecting a bottom surface of the UV exposure chamber and aligned to face a main surface of the reticle,
wherein the UV lamp is configured to irradiate the main surface of the reticle with the UV beam to remove an oxide layer on the main surface of the reticle, the reticle being supported by the supporting portion.

20. The substrate processing apparatus of claim 19, wherein the supporting portion comprises:
a pivot configured to rotate about a rotating axis in a direction intersecting the first direction; and
a bracket connected to the pivot and configured to rotate about the rotating axis, the bracket contacting an edge of the main surface of the reticle,
wherein the bracket is configured to rotate together with the pivot and contact the reticle when the reticle is below the pivot in the first direction.
